(19) United States
(12) Patent Application Publication
(10) Pub. No.: US 2017/0069862 A1
(43) Pub. Date: Mar. 9, 2017

(54) PHOTOVOLTAIC CELL AND METHOD OF MANUFACTURING THE SAME, MANUFACTURE DEVICE AND PRODUCTION LINE FOR PHOTOVOLTAIC CELL

(71) Applicants: BOE TECHNOLOGY GROUP CO., LTD., Beijing (CN); HEFEI BOE OPTOELECTRONICS TECHNOLOGY CO., LTD., Beijing (CN)

(72) Inventor: Gangqi HUANG, Beijing (CN)

(21) Appl. No.: 15/160,210

(22) Filed: May 20, 2016

(30) Foreign Application Priority Data
Sep. 6, 2015 (CN) 201510559534.2

(51) Int. Cl. H01L 51/44; H01L 51/00; H01L 51/42

(52) U.S. Cl. CPC H01L 51/448; H01L 51/441; H01L 51/4206; H01L 51/0003; H01L 51/0021

(57) ABSTRACT

The present invention provides a photovoltaic cell and a method of manufacturing the same, a manufacture device and a production line for a photovoltaic cell. The method of manufacturing a photovoltaic cell includes steps of: forming an anode layer on a substrate; forming, by spin coating, a donor-acceptor polymer mixed film layer on the substrate; and forming a cathode layer on the substrate. During the formation of the donor-acceptor polymer mixed film layer on the substrate by spin coating, a DC electric field is applied to the donor-acceptor polymer mixed film layer. By using the method, orientations of the molecules in the polymer chain of the donor-acceptor polymer mixed film layer tend to be consistent with each other under the effect of the DC electrical field, so that a transmission rate of carriers during the photoelectric conversion is increased, thereby improving the efficiency and the stability of the photovoltaic cell.

### FIELD OF THE INVENTION

The present invention relates to the field of photovoltaic cell technology, and specifically relates to a photovoltaic cell and a method of manufacturing the same, a manufacture device and a production line for a photovoltaic cell.

### BACKGROUND OF THE INVENTION

Solar energy has been widely used as a renewable energy source. A polymer photovoltaic cell is a solar product converting solar light energy into electrical energy, and has been focused in a research of photoelectric conversion devices due to the advantages of low cost, simple manufacture process and the like.

A common structure of a photoelectric conversion film layer inside the polymer photovoltaic cell is a structure of donor-acceptor polymer mixed heterojunction. The polymer photovoltaic cell operates in such a procedure that, the structure of donor-acceptor polymer mixed heterojunction is excited, by light irradiation, to generate photon-generated excitons, and then the excitons diffuse to spread charges, and the charges are transmitted and collected. However, the photoelectric conversion film layer provided with the structure of donor-acceptor polymer mixed heterojunction has a problem of low mobility of carriers in an organic material, which causes the polymer photovoltaic cell to have low photoelectric conversion efficiency.

A conventional process of manufacturing such polymer photovoltaic cell is generally a technology of spin coating to form a film, that is, forming a photoelectric conversion film layer, provided with the structure of donor-acceptor polymer mixed heterojunction, by spin coating. Specifically, the manufacture process includes the steps of spinning, by a spin coater, a mixed solution of donors and acceptors to a cleaned anode substrate, and then evaporating a metal cathode, so as to form a complete structure of a photoelectric conversion device. However, the device manufactured by such manufacture technology suffers from an unstable performance, and the device has a low photoelectric conversion efficiency for the reason that the mobility of carriers of an organic material is much lower than that of an inorganic material.

### SUMMARY OF THE INVENTION

In view of the above technical problems existing in the prior art, the present invention provides a photovoltaic cell and a method of manufacturing the same, a manufacture device and a production line for a photovoltaic cell. By using the method of manufacturing a photovoltaic cell, orientations of the molecules in the polymer chain of a donor-acceptor polymer mixed film layer tend to be consistent with each other under a direct current (DC) electrical field, which results in an improved mobility of carriers inside the donor-acceptor polymer mixed film layer during the photoelectric conversion, so that a transmission rate of carriers in the donor-acceptor polymer mixed film layer during the photoelectric conversion is increased, and an energy loss inside the mixed film layer, caused by charge recombination, is reduced, thereby improving the efficiency and the stability of the photovoltaic cell.

The present invention provides a method of manufacturing a photovoltaic cell, which includes steps of: forming an anode layer on a substrate; forming, by spin coating, a donor-acceptor polymer mixed film layer on the substrate; and forming a cathode layer on the substrate. Here, during the formation of the donor-acceptor polymer mixed film layer on the substrate by spin coating, a DC electric field is applied to the donor-acceptor polymer mixed film layer, which is being formed by spin coating.

Preferably, the DC electric field has a direction perpendicular and directing to the substrate.

Preferably, the step of applying, during the formation of the donor-acceptor polymer mixed film layer on the substrate by spin coating, a DC electric field to the donor-acceptor polymer mixed film layer being spin coated includes: connecting a positive electrode of a DC power supply to a metal conductive sheet, the metal conductive sheet being a positive plate of the DC electric field; using, as a negative plate of the DC electric field, a spinning plate used for carrying the substrate and included in a spin-coating apparatus for spin coating the donor-acceptor polymer mixed film layer, and electrically connecting a negative electrode of the DC power supply to a spinning axis of the spinning plate, so as to form the DC electric field between the metal conductive sheet and the spinning plate.

Preferably, the metal conductive sheet is a copper sheet, and the negative electrode of the DC power supply is electrically connected to the spinning axis of the spinning plate through a carbon brush.

Preferably, the metal conductive sheet and the spinning plate are disposed on different sides of the substrate, respectively, and the metal conductive sheet and the spinning plate are parallel and exactly facing to each other.

Preferably, the DC electric field has an intensity ranging from 1 kV/cm to 5 kV/cm.

Preferably, the step of forming the donor-acceptor polymer mixed film layer on the substrate by spinning coating includes: stirring a donor polymeric material, an acceptor polymeric material and a solvent together, so as to mix them uniformly to form a donor-acceptor polymer mixed solution; spin coating, on the substrate provided with the anode layer, the donor-acceptor polymer mixed solution; and, performing a drying process, after spin coating, on the substrate.

Preferably, the donor polymeric material, the acceptor polymeric material and the solvent are stirred in a magnetic stirring device for 2-5 hours, and, when starting to spin coat the donor-acceptor polymer mixed solution on the substrate provided with the anode layer, the solution is spin coated at a spinning rate of 600 rounds/min for 1 minute, and then is spin coated at a spinning rate of 1000 rounds/min for 20 seconds, and the drying process is performed on the substrate in a dryer at a temperature of 120□ for 30 minutes.

Preferably, the donor polymeric material includes a 3-hexyl-thiophene polymer, the acceptor polymeric material includes a polyethylene dioxythiophene, and the solvent includes an orthodichlorobenzene.

Preferably, a buffer layer is formed on the substrate, after the anode layer is formed on the substrate and before the donor-acceptor polymer mixed film layer is formed on the substrate by spin coating.

Preferably, the buffer layer includes a 3, 4-ethylenedioxythiophene monomer: polystyrene sulfonate macromolecular polymer, and the step of forming the buffer layer includes: spin coating, on the substrate provided with the anode layer, an aqueous solution of the 3, 4-ethylenedioxythiophene monomer: polystyrene sulfonate macromolecular polymer, and then performing a drying process on the substrate.

Preferably, during the formation of the buffer layer by spin coating, the aqueous solution of the 3, 4-ethylenedioxythiophene monomer: polystyrene sulfonate macromolecular polymer is spin coated at a spinning rate of 3500 rounds/min for 1 minute, and the drying process is performed on the substrate in a dryer at a temperature of 120□ for 30 minutes.

Preferably, the step of forming the anode layer on the substrate further includes: cleaning, after forming the anode layer, the substrate with an organic cleaning agent, and blowing, with nitrogen gas, a surface of the anode layer to be dry; then, cleaning, by ultrasonic oscillation, the substrate additionally with acetone, and cleaning the substrate with deionized water; then, cleaning, by ultrasonic oscillation, the substrate additionally with ethanol, and cleaning the substrate with deionized water; and finally, blowing a surface of the anode layer to be dry with nitrogen gas, and disposing the substrate into a dryer to perform a drying process.

Preferably, the step of forming the cathode layer on the substrate includes: forming, by evaporating, a metal cathode layer by using a vacuum coating machine.

The present invention also provides a photovoltaic cell, which is manufactured by using the above method.

Preferably, the photovoltaic cell includes a substrate, and further includes an anode layer, a buffer layer, a donor-acceptor polymer mixed film layer and a cathode layer, which are disposed sequentially on the substrate and overlapped with each other.

The present invention further provides a manufacture device of a photovoltaic cell, which includes a spin coating member including a spinning plate for carrying a substrate on which spin coating is to be performed and capable of spinning around the spinning axis thereof, and further includes a electric field applying member being arranged in correspondence with the spinning plate and used for applying a DC electric field, to which the donor-acceptor polymer mixed film layer is subjected, during the formation of the donor-acceptor polymer mixed film layer on the substrate by spin coating.

Preferably, the electric field applying member includes a DC power supply, a positive plate and a negative plate, the positive plate being electrically connected to a positive electrode of the DC power supply, and the negative plate being electrically connected to a negative electrode of the DC power supply; and wherein, a metal conductive sheet is used as the positive plate, the spinning plate is used as the negative plate, the negative electrode of the DC power supply is electrically connected to the spinning axis of the spinning plate, and the metal conductive sheet and the spinning plate are parallel and exactly facing to each other, and are positioned on different sides of the substrate, respectively.

Preferably, the metal conductive sheet is a copper sheet, and the negative electrode of the DC power supply is electrically connected to the spinning axis of the spinning plate through a carbon brush.

The present invention also provides a production line of a photovoltaic cell, which includes the above manufacture device of a photovoltaic cell.

The beneficial effects of the present invention are as follows. In the method of manufacturing a photovoltaic cell provided by the present invention, by the means of applying a DC electric field to a donor-acceptor polymer mixed film layer being spin coated, orientations of the molecules in the polymer chain of the donor-acceptor polymer mixed film layer tend to be consistent with each other under the effect of the DC electrical field, which makes molecules to be arranged orderly in the polymer chain and pushes adjacent molecules in the polymer chain to be parallel to each other. Such arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell.

The photovoltaic cell provided by the present invention is manufactured by using the above method, so orientations of the molecules in the polymer chain of the donor-acceptor polymer mixed film layer tend to be consistent with each other under the effect of the DC electrical field, which makes molecules to be arranged orderly in the polymer chain and pushes adjacent molecules in the polymer chain to be parallel to each other. Such arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell.

In the manufacture device of a photovoltaic cell provided by the present invention, by providing a electric field applying member, the donor-acceptor polymer mixed film layer being spin coated can be subjected to a DC electric field applied by the electric field applying member, wherein the DC electric field causes the orientations of the molecules in the polymer chain of the donor-acceptor polymer mixed film layer to be consistent with each other, so as to make molecules to be arranged orderly in the polymer chain and push adjacent molecules in the polymer chain to be parallel to each other. Such arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell.

The production line of a photovoltaic cell provided by the present invention uses the above manufacture device of a photovoltaic cell, so that the photoelectric conversion efficiency and the stability of the photovoltaic cell manufactured in the production line are significantly improved.

### BRIEF DESCRIPTION OF THE DRAWINGS

FIG. 1 is a flowchart of a method of manufacturing a photovoltaic cell, according to a first embodiment of the present invention;

FIG. 2 is a structural cross-sectional view of a photovoltaic cell according to a second embodiment of the present invention; and

FIG. 3 is a structural schematic diagram of a manufacture device of a photovoltaic cell, according to a third embodiment of the present invention.

### DESCRIPTION OF REFERENCE NUMERALS

1. substrate; 2. anode layer; 3. buffer layer; 4. donor-acceptor polymer mixed film layer; 5. cathode layer; 6. spin coating member; 61. spinning plate; 62. spinning axis; 7. electric field applying member; 71. DC power supply; 72. positive plate.

### DETAILED DESCRIPTION OF THE EMBODIMENTS

To make those skilled in the art better understand the technical solutions of the present invention, a photovoltaic cell and a method of manufacturing the same, a manufacture device and a production line for a photovoltaic cell provided by the present invention will be described in detail below in conjunction with the accompanying drawings and the specific implementations.

### First Embodiment

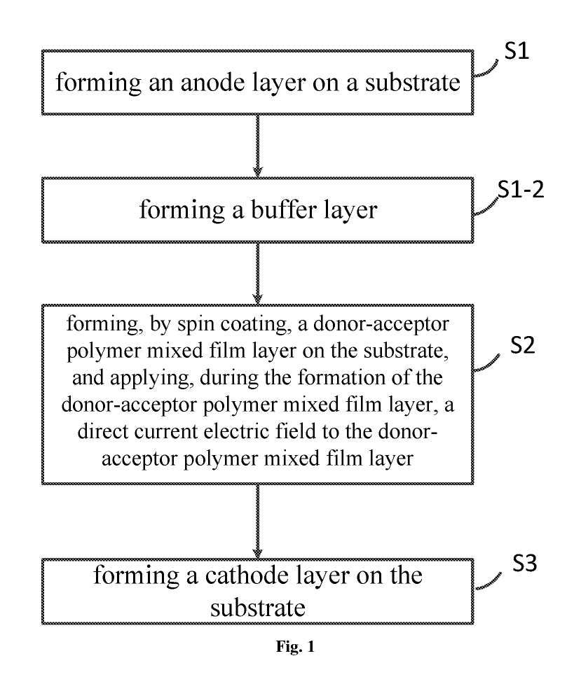

The present embodiment provides a method of manufacturing a photovoltaic cell, and as shown in FIG. 1, the method includes: in a step S1, an anode layer is formed on a substrate; in a step S2, a donor-acceptor polymer mixed film layer is formed on the substrate, which is provided with the anode layer, by spin coating; and in a step S3, a cathode layer is formed on the substrate which is provided with the donor-acceptor polymer mixed film layer, wherein in the step S2 of forming the donor-acceptor polymer mixed film layer on the substrate by spin coating, a DC electric field is applied to the donor-acceptor polymer mixed film layer, which is being formed by spin coating.

According to the present embodiment, by the means of applying a DC electric field to a donor-acceptor polymer mixed film layer being spin coated, orientations of the molecules in the polymer chain of the donor-acceptor polymer mixed film layer tend to be consistent with each other under the effect of the DC electrical field, which makes molecules to be arranged orderly in the polymer chain and pushes adjacent molecules in the polymer chain to be parallel to each other. Such arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell. In addition, such orderly arrangement of the molecules in the polymer chains is capable of increasing an area of an interface where the donor and the acceptor are in contact with each other, which facilitates the spread of excitons and the generation of charges inside the donor-acceptor polymer mixed film layer during the photoelectric conversion; and it also provides a better transmission path of charges, thereby improving the efficiency and the stability of the photovoltaic cell.

Here, a DC electric field having a direction perpendicular to the substrate is applied during the formation of the donor-acceptor polymer mixed film layer by spin coating, and the direction of the DC electric field is directed to the substrate. The DC electric field has an intensity ranging from 1 kV/cm to 5 kV/cm. By applying the above DC electric field to the donor-acceptor polymer mixed film layer during the spin coating, orientations of the molecules in the polymer chain of the donor-acceptor polymer mixed film layer tend to be consistent with each other, such that the carriers can be transmitted in the polymer chain more easily, and thus the efficiencies of collecting carriers by the anode and cathode layers of the photovoltaic cell are improved, and the mobility of carriers is increased, resulting in an improvement of the performance of the photovoltaic cell. In the meantime, the consistence of orientations of the molecules in the polymer chain of the donor-acceptor polymer mixed film layer, under the effect of the DC electric field, may provides a transmission path of carriers having a better conductivity, and a short current of the photovoltaic cell will be increased accordingly, thereby improving the photoelectric conversion efficiency of the photovoltaic cell.

Specifically, in the step S1, the anode layer is formed on the substrate. Here, the anode layer is made of a material of indium tin oxide by a process of sputtering deposition, and the manufacture method thereof is a conventional method, of which the description is omitted herein.

In the present embodiment, the step S1 further includes, after forming the anode layer on the substrate, the steps of: first, cleaning the substrate with an organic cleaning agent, and blowing, with nitrogen gas, a surface of the anode layer to be dry; then, cleaning, by ultrasonic oscillation, the substrate additionally with acetone for 10 minutes, and cleaning the substrate with deionized water for 10 minutes; then, cleaning, by ultrasonic oscillation, the substrate additionally with ethanol for 10 minutes, and cleaning the substrate with deionized water; and finally, blowing a surface of the anode layer to be dry with nitrogen gas again, and disposing the substrate into a dryer to perform a drying process, the drying duration being not less than two hours.

Specifically, the step S2 includes: stirring, in a magnetic stirring device, a donor polymeric material, an acceptor polymeric material and a solvent for 2-5 hours, so as to mix them uniformly to form a donor-acceptor polymer mixed solution; then, spin coating (for example, by using a bench spin coater), on the substrate provided with the anode layer and subjected to the DC electric field (i.e., the substrate on which the operations of the step S1 have been performed), the donor-acceptor polymer mixed solution, wherein the spinning rate is 600 rounds/minute when starting to spin coat, and after spin coating for 1 minute, the spinning rate is adjusted to 1000 rounds/minute and spin coating is continued for 20 seconds; thereafter, disposing the substrate into a dryer at a temperature of 120° C. to dry for 30 minutes. Here, the donor polymer material includes a 3-hexyl thiophene polymer (P3HT), the acceptor polymer material includes a polyethylene dioxythiophene (PCBM), and the solvent includes an orthodichlorobenzene, but the present invention is not limited thereto.

In the present embodiment, the DC electric field is applied to the donor-acceptor polymer mixed film layer, which is being formed by spin coating, during the formation of the donor-acceptor polymer mixed film layer by spin coating (i.e., the step S2). The step of applying the DC electric field includes: connecting a positive electrode of a DC power supply to a copper sheet, the copper sheet being a positive plate of the DC electric field; using, as a negative plate of the DC electric field, a spinning plate used for carrying the substrate and included in a spin-coating apparatus for spin coating the donor-acceptor polymer mixed film layer, and electrically connecting a negative electrode of the DC power supply to a spinning axis of the spinning plate through a carbon brush, so as to form the DC electric field between the copper sheet and the spinning plate. By such an arrangement, the DC electric field may be applied to the donor-acceptor polymer mixed film layer being spin coated, such that a desired change will occur in the microstructure of the donor-acceptor polymer mixed film layer.

In the present embodiment, the method may further include a step S1-2 of forming a buffer layer, after the step S1 and before the step S2. The step of forming the buffer layer includes: spin coating, on the substrate, an aqueous solution of the 3, 4-ethylenedioxythiophene monomer: polystyrene sulfonate macromolecular polymer, at a spinning rate of 3500 rounds/minute for 1 minute; then, drying the substrate in a dryer at a temperature of 120° C. for 30 minutes. The formation of the buffer layer may reduce a series resistance of the photovoltaic cell, increase a short current of the photovoltaic cell, and improve a performance thereof.

In the present embodiment, the step S3 includes: forming, by evaporating, a metal cathode layer by using a vacuum coating machine. For example, the cathode layer is made of aluminum. Specifically, the formation of the cathode layer includes the following steps. A metal material of aluminum is disposed into a cavity of the vacuum coating machine, a vacuum in the cavity is created by a mechanical pump so as to make an air pressure within the cavity no higher than 5 Pa, and thereafter a vacuum in the cavity is created by a molecular pump so as to make an air pressure within the cavity no higher than 8×10⁴ Pa. Then, in the above vacuum environment, certain voltage and current are applied to the cavity so as to make the aluminum material in the cavity sublimated, and thereafter a vapor of the aluminum material is cooled on a surface of the substrate, which is provided with the donor-acceptor polymer mixed film layer by spin coating and is subjected to the DC electric field, so as to form the cathode layer.

In the method of manufacturing a photovoltaic cell according to the present embodiment, by the means of applying a DC electric field to a donor-acceptor polymer mixed film layer being spin coated, orientations of the molecules in the polymer chain of the donor-acceptor polymer mixed film layer tend to be consistent with each other under the effect of the DC electrical field, which makes molecules to be arranged orderly in the polymer chain and pushes adjacent molecules in the polymer chain to be parallel to each other. Such an arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such an orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell.

### Second Embodiment

The present embodiment provides a photovoltaic cell, which is manufactured by using the method according to the first embodiment.

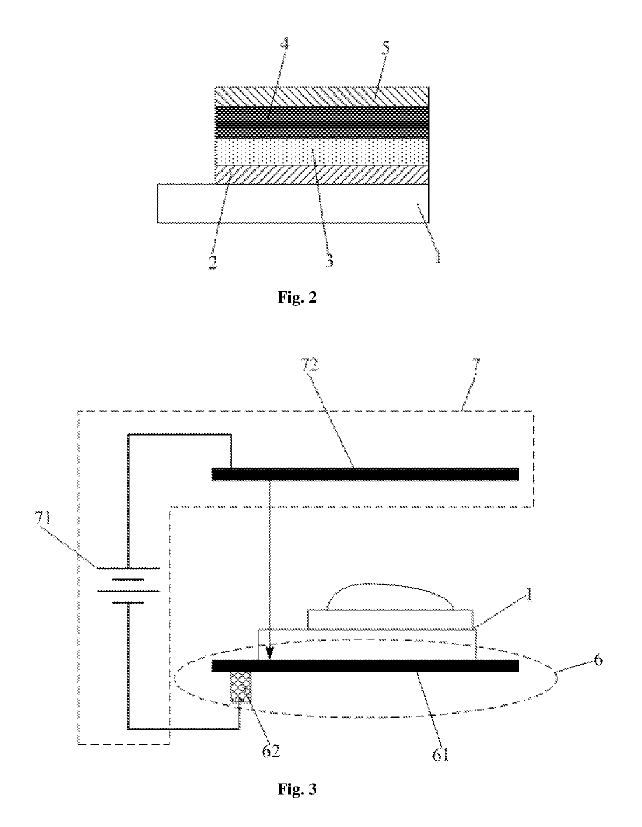

As shown in FIG. 2, the photovoltaic cell includes a substrate 1, and further includes an anode layer 2, a buffer layer 3, a donor-acceptor polymer mixed film layer 4 and a cathode layer 5, which are disposed sequentially on the substrate 1 and overlapped with each other.

The photovoltaic cell is manufactured by using the method according to the first embodiment. In the photovoltaic cell, orientations of the molecules in the polymer chain of the donor-acceptor polymer mixed film layer, which is a photoelectric conversion layer, tend to be consistent with each other, and it makes molecules to be arranged orderly in the polymer chain and adjacent molecules in the polymer chain to be parallel to each other. Such an arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such an orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell.

### Third Embodiment

The present embodiment provides a manufacture device of a photovoltaic cell. As shown in FIG. 3, the manufacture device includes a spin coating member 6, which includes a spinning plate 61 for carrying the substrate 1 on which spin coating is to be performed and capable of spinning around the spinning axis 62 thereof, and the manufacture device further includes a electric field applying member 7, which is arranged in correspondence with the spinning plate 61 and is used for applying a DC electric field, to which the donor-acceptor polymer mixed film layer is subjected, during the formation of the donor-acceptor polymer mixed film layer on the substrate 1 by spin coating.

In the present embodiment, the electric field applying member 7 includes a DC power supply 71, a positive plate 72 and a negative plate, the positive plate 72 being electrically connected to a positive electrode of the DC power supply 71, and the negative plate being electrically connected to a negative electrode of the DC power supply 71. A copper sheet is used as the positive plate 72, the spinning plate 61 is used as the negative plate, wherein the negative electrode of the DC power supply 71 is electrically connected to the spinning axis 62 of the spinning plate 61 through a carbon brush, and the copper sheet serving as the positive plate 72 and the spinning plate 61 serving as the negative plate are parallel and exactly facing to each other, and are positioned on different sides of the substrate 1 on which spin coating is to be performed, respectively. By such an arrangement, a DC electric field having a direction perpendicular and directing to the substrate 1 is formed between the copper sheet and the spinning plate 61, so that the donor-acceptor polymer mixed film layer, which is being spin coated, is subjected to the DC electric field.

In the manufacture device of a photovoltaic cell according to the present embodiment, by providing the electric field applying member 7, the donor-acceptor polymer mixed film layer being spin coated can be subjected to a DC electric field applied by the electric field applying member 7, wherein the DC electric field causes the orientations of the molecules in the polymer chain of the donor-acceptor polymer mixed film layer to be consistent with each other, so as to make molecules to be arranged orderly in the polymer chain and push adjacent molecules in the polymer chain to be parallel to each other. Such an arrangement is capable of improving the mobility of carriers inside the donor-acceptor polymer mixed film layer during the photoelectric conversion, so that a transmission rate of carriers in the donor-acceptor polymer mixed film layer during the photoelectric conversion is increased, thereby improving the efficiency of the photovoltaic cell; in the meantime, such an orderly arrangement of the molecules in the polymer chains is capable of reducing a probability of charge recombination inside the donor-acceptor polymer mixed film layer during the photoelectric conversion, thereby reducing an energy loss inside the mixed film layer caused by charge recombination and improving the stability of the photovoltaic cell.

### Fourth Embodiment

The present embodiment provides a production line of a photovoltaic cell, which includes the manufacture device according to the third embodiment.

By using the manufacture device according to the third embodiment, the photoelectric conversion efficiency and the stability of the photovoltaic cell manufactured in the production line of a photovoltaic cell are significantly improved.

It can be understood that the foregoing implementations are merely exemplary implementations used for describing the principle of the present invention, but the present invention is not limited thereto. Those of ordinary skill in the art may make various variations and improvements without departing from the spirit and essence of the present invention, and these variations and improvements shall fall into the protection scope of the present invention.

What is claimed is:

1. A method of manufacturing a photovoltaic cell, comprising steps of:
forming an anode layer on a substrate;
forming, by spin coating, a donor-acceptor polymer mixed film layer on the substrate; and
forming a cathode layer on the substrate,
wherein, during the formation of the donor-acceptor polymer mixed film layer on the substrate by spin coating, a direct current electric field is applied to the donor-acceptor polymer mixed film layer, which is being formed by spin coating.

2. The method according to claim 1, wherein the direct current electric field has a direction perpendicular and directing to the substrate.

3. The method according to claim 2, wherein the step of applying, during the formation of the donor-acceptor polymer mixed film layer on the substrate by spin coating, a direct current electric field to the donor-acceptor polymer mixed film layer being spin coated includes:
connecting a positive electrode of a direct current power supply to a metal conductive sheet, the metal conductive sheet being a positive plate of the direct current electric field; and
using, as a negative plate of the direct current electric field, a spinning plate used for carrying the substrate and included in a spin-coating apparatus for spin coating the donor-acceptor polymer mixed film layer, and electrically connecting a negative electrode of the direct current power supply to a spinning axis of the spinning plate, so as to form the direct current electric field between the metal conductive sheet and the spinning plate.

4. The method according to claim 3, wherein the metal conductive sheet is a copper sheet, and the negative electrode of the direct current power supply is electrically connected to the spinning axis of the spinning plate through a carbon brush.

5. The method according to claim 3, wherein the metal conductive sheet and the spinning plate are disposed on different sides of the substrate, respectively, and the metal conductive sheet and the spinning plate are parallel and exactly facing to each other.

6. The method according to claim 2, wherein the direct current electric field has an intensity ranging from 1 kV/cm to 5 kV/cm.

7. The method according to claim 1, wherein the step of forming the donor-acceptor polymer mixed film layer on the substrate by spinning coating includes:
stirring a donor polymeric material, an acceptor polymeric material and a solvent together, so as to mix them uniformly to form a donor-acceptor polymer mixed solution; and
spin coating, on the substrate provided with the anode layer, the donor-acceptor polymer mixed solution; and
performing, after spin coating, a drying process on the substrate.

8. The method according to claim 7,
wherein the donor polymeric material, the acceptor polymeric material and the solvent are stirred in a magnetic stirring device for 2-5 hours;
wherein, when starting to spin coat the donor-acceptor polymer mixed solution on the substrate provided with the anode layer, the solution is spin coated at a spinning rate of 600 rounds/min for 1 minute, and then is spin coated at a spinning rate of 1000 rounds/min for 20 seconds; and
wherein the drying process is performed on the substrate in a dryer at a temperature of 120° C. for 30 minutes.

9. The method according to claim 7, wherein the donor polymeric material includes a 3-hexyl-thiophene polymer, the acceptor polymeric material includes a polyethylene dioxythiophene, and the solvent includes an orthodichlorobenzene.

10. The method according to claim 1, further comprising:
forming, after forming the anode layer on the substrate and before forming the donor-acceptor polymer mixed film layer on the substrate by spin coating, a buffer layer on the substrate.

11. The method according to claim 10, wherein the buffer layer includes a 3, 4-ethylenedioxythiophene monomer: polystyrene sulfonate macromolecular polymer, and the step of forming the buffer layer includes:
spin coating, on the substrate provided with the anode layer, an aqueous solution of the 3, 4-ethylenedioxythiophene monomer: polystyrene sulfonate macromolecular polymer, and then performing a drying process on the substrate.

12. The method according to claim 11, wherein during the formation of the buffer layer by spin coating, the aqueous solution of the 3, 4-ethylenedioxythiophene monomer: polystyrene sulfonate macromolecular polymer is spin coated at a spinning rate of 3500 rounds/min for 1 minute, and the drying process is performed on the substrate in a dryer at a temperature of 120° C. for 30 minutes.

13. The method according to claim 1, wherein the step of forming the anode layer on the substrate further includes:
cleaning, after forming the anode layer, the substrate with an organic cleaning agent, and blowing, with nitrogen gas, a surface of the anode layer to be dry;
cleaning, by ultrasonic oscillation, the substrate additionally with acetone, and cleaning the substrate with deionized water;
cleaning, by ultrasonic oscillation, the substrate additionally with ethanol, and cleaning the substrate with deionized water; and
blowing a surface of the anode layer to be dry with nitrogen gas, and disposing the substrate into a dryer to perform a drying process.

14. The method according to claim 1, wherein the step of forming the cathode layer on the substrate includes:
forming, by evaporating, a metal cathode layer by using a vacuum coating machine.

15. A photovoltaic cell, which is manufactured by using the method according to claim 1.

16. The photovoltaic cell according to claim 15, wherein the photovoltaic cell includes a substrate, and further includes an anode layer, a buffer layer, a donor-acceptor polymer mixed film layer and a cathode layer disposed sequentially on the substrate and overlapped with each other.

17. A manufacture device of a photovoltaic cell, comprising:
a spin coating member, which includes a spinning plate for carrying a substrate on which spin coating is to be performed and capable of spinning around a spinning axis thereof; and
a electric field applying member, which is arranged in correspondence with the spinning plate and used for applying a direct current electric field, to which a donor-acceptor polymer mixed film layer is subjected, during the formation of the donor-acceptor polymer mixed film layer on the substrate by spin coating.

18. The manufacture device of a photovoltaic cell according to claim 17, wherein the electric field applying member includes a direct current power supply, a positive plate and a negative plate, the positive plate being electrically connected to a positive electrode of the direct current power supply, and the negative plate being electrically connected to a negative electrode of the direct current power supply; and
wherein a metal conductive sheet is used as the positive plate, the spinning plate is used as the negative plate, the negative electrode of the direct current power supply is electrically connected to the spinning axis of the spinning plate, and the metal conductive sheet and the spinning plate are parallel and exactly facing to each other, and are positioned on different sides of the substrate, respectively.

19. The manufacture device of a photovoltaic cell according to claim 18, wherein the metal conductive sheet is a copper sheet, and the negative electrode of the direct current power supply is electrically connected to the spinning axis of the spinning plate through a carbon brush.

20. A production line of a photovoltaic cell, comprising the manufacture device of a photovoltaic cell according to claim 17.
